(19) United States
(12) Patent Application Publication
(10) Pub. No.: US 2012/0056181 A1
(43) Pub. Date: Mar. 8, 2012

(54) METHOD OF MANUFACTURING ELECTRONIC ELEMENT AND ELECTRONIC ELEMENT

(75) Inventors: Masanao Kamata, Tokyo (JP); Hiroaki Yamana, Kanagawa (JP); Iwao Yagi, Kanagawa (JP); Noriyuki Kawashima, Kanagawa (JP)

(73) Assignee: SONY CORPORATION, Tokyo (JP)

(21) Appl. No.: 13/218,907

(22) Filed: Aug. 26, 2011

(30) Foreign Application Priority Data
Sep. 3, 2010 (JP) P2010-197985

(51) Int. Cl. H01L 23/522; H01L 21/28; H05K 3/00; H01L 29/786; H05K 1/02; H01L 51/44; H01L 21/768; H01L 51/48

(52) U.S. Cl. 257/57; 438/623; 438/586; 438/82; 257/734; 174/254; 136/263; 29/829; 257/40; 257/E21.575; 257/E21.158; 257/E51.012; 257/E23.142; 257/E29.273

(57) ABSTRACT

There is provided a method of manufacturing an electronic element for forming the electronic element including one or more wiring layers and an organic insulating layer stacked on a substrate. The method includes a wiring layer formation step of forming the wiring layer on the substrate; an organic insulating layer formation step of forming an organic insulating layer on the wiring layer; and an irradiation step of irradiating a short-circuit portion of the wiring layer through the organic insulating layer with a laser beam having a wavelength transmissive through the organic insulating layer.

### BACKGROUND

The present disclosure relates to a method of manufacturing an electronic element, including one or more wiring layers and an organic insulating layer stacked on a substrate, and to an electronic element.

In an electronic display element using an organic thin film transistor (organic TFT), such as a flexible organic EL (Electro Luminescence) display and a flexible electronic paper, or an electronic element using the organic TFT, such as a flexible printed circuit board, an organic thin-film solar cell, and a touch panel, circuit lines on a substrate have been increasingly reduced in size or increased in density with improvement in display performance or integration. Such circuit lines have been typically formed using a photography process but recently formed even using a printing/coating process, and thus a yield of non-defective products of the circuit lines is decreased with improvement in performance of an electronic circuit board. In particular, even one line-short-circuit defect, formed on a board due to a foreign substance or pattern residue, has a fatal effect, and such a board is hard to be shipped as a product and is often disposed of as a defective product. This inevitably leads to a need of a technique for repairing a line-short-circuit defect in order to improve a manufacturing yield, namely, to reduce manufacturing cost.

In the past, Japanese Patent No. 3406222 has disclosed a technique for repairing a line-short-circuit defect in a thin film transistor having an insulating layer which is made of an inorganic material. In the technique, an in-layer short-circuit portion of an exposed wiring layer is removed by laser processing to recover insulation performance, and then an insulating layer is deposited.

Japanese Unexamined Patent Application Publication No. 2001-77198 has disclosed a method where laser processing and laser CVD are used together to repair interlayer short-circuit at a crossing or overlap point of upper and lower wiring patterns.

### SUMMARY

However, laser processing is performed in the previous technique described in Japanese Patent No. 3406222, which causes rising of a processed end of the wiring layer or formation of particles, called debris, having a diameter of about several nanometers to several tens micrometers. While such phenomena may be somewhat reduced by using femtosecond laser or picosecond laser having a short pulse width, the phenomena are principally hard to be eliminated. A structure such as rising of the processed end or the debris has been particularly disadvantageous when an organic insulating layer is deposited on the wiring layer. In other words, when the organic insulating layer is formed on the wiring layer, the structure breaks through the organic insulating layer, leading to interlayer short-circuit at a three-dimensional crossing point of upper and lower lines with the organic insulating layer in between. Even if rising of the processed end or the debris fails to break through the organic insulating layer, interlayer withstanding voltage between the upper and lower lines is reduced, and thus interlayer short-circuit is eventually induced. The organic thin film transistor used for the flexible organic EL display or the flexible electronic paper has been particularly significantly affected by the above disadvantage in repairing the short-circuit portion since an organic insulating material is used for an interlayer insulating layer of a capacitor section having an extremely small thickness of 1 micrometer or less.

The previous method described in Japanese Unexamined Patent Application Publication No. 2001-77198 uses laser CVD, which principally causes a process and equipment to be complicated, and causes repair operation time to be lengthened.

In this way, it has been hard to repair, by the previous methods, the line-short-circuit defect in the electronic element having the insulating layer which is made of an organic material, or even if the defect is repaired, complicated process, complicated equipment, and long operation time are inevitable.

It is desirable to provide a method of manufacturing an electronic element having an organic insulating layer, allowing a line-short-circuit portion in the element to be insulated in a simple method, and provide an electronic element.

A first method of manufacturing an electronic element according to an embodiment of the disclosure for forming the electronic element including one or more wiring layers and an organic insulating layer stacked on a substrate, includes the following steps (A) to (C):

(A) Wiring layer formation step of forming the wiring layer on the substrate,

(B) Organic insulating layer formation step of forming an organic insulating layer on the wiring layer, and

(C) Irradiation step of irradiating a short-circuit portion of the wiring layer through the organic insulating layer with a laser beam having a wavelength transmissive through the organic insulating layer.

A second method of manufacturing an electronic element according to an embodiment of the disclosure for forming the electronic element having one or more wiring layers and an organic insulating layer stacked on a substrate, includes the following steps (A) to (C):

(A) Wiring layer formation step of forming a wiring layer on a substrate,

(B) Organic insulating layer formation step of forming an organic insulating layer on the wiring layer, and

(C) Irradiation step of irradiating a short-circuit portion of the wiring layer through the substrate with a laser beam having a wavelength transmissive through the substrate.

In the first or second method of manufacturing the electronic element according to the embodiment of the disclosure, the wiring layer and the organic insulating layer are formed on the substrate, and then the short-circuit portion of the wiring layer is irradiated through the organic insulating layer with the laser beam having the wavelength transmissive through the organic insulating layer, or irradiated through the substrate with the laser beam having the wavelength transmissive through the substrate. This causes a laser-irradiated region in the short-circuit portion to be removed while suppressing an effect of the laser beam on the organic insulating layer or the substrate in contact with a top or bottom of the short-circuit portion, so that the short-circuit portion is insulated. In addition, laser irradiation is performed in a state where the organic insulating layer is formed on the short-circuit portion unlike a method in the past, where the organic insulating layer is formed after laser irradiation, which reduces a possibility that a structure such as rising of the processed end or the debris breaks through the organic insulating layer. Accordingly, when another wiring layer is formed on the organic insulating layer, occurrence of interlayer short-circuit is avoided.

An electronic element according to an embodiment of the disclosure includes one or more wiring layers and an organic insulating layer stacked on a substrate, and has, in the same layer as the wiring layer, a cavity enclosed by the wiring layer and the organic insulating layer or the substrate in contact with a top or bottom of the wiring layer.

In the electronic element according to the embodiment of the disclosure, since the electronic element has, in the same layer as the wiring layer, the cavity enclosed by the wiring layer and the organic insulating layer or the substrate in contact with the top or bottom of the wiring layer, the short-circuit portion of the wiring layer is insulated by the cavity. In addition, the organic insulating layer or the substrate in contact with the top or bottom of the cavity is not broken through by the structure such as rising of a processed end or debris, avoiding occurrence of interlayer short-circuit between the wiring layer in the same layer as the cavity and another wiring layer on the organic insulating layer.

According to the first or second method of manufacturing the electronic element of the embodiment of the disclosure, the organic insulating layer is formed on the wiring layer, and then the short-circuit portion of the wiring layer is irradiated through the organic insulating layer with the laser beam having the wavelength transmissive through the organic insulating layer, or irradiated through the substrate with the laser beam having the wavelength transmissive through the substrate, making it possible to insulate line-short-circuit in the electronic element having the organic insulating layer in a simple process.

According to the electronic element of the embodiment of the disclosure, the electronic element has, in the same layer as the wiring layer, the cavity enclosed by the wiring layer and the organic insulating layer or the substrate in contact with the top or bottom of the wiring layer, making it possible to insulate the short-circuit portion of the wiring layer by the cavity.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

(A) of FIG. 1 is a plan diagram illustrating a configuration of an example of a wiring layer as a repairing object as viewed in a vertical direction to a substrate plane, in a method of manufacturing an electronic element according to a first embodiment of the disclosure, and (B) of FIG. 1 is a section diagram illustrating a configuration along a IB-IB line in (A) of FIG. 1.

(A) of FIG. 2 is a plan diagram illustrating a configuration of an example of a short-circuit portion of the wiring layer illustrated in (A) and (B) of FIG. 1 as viewed in a vertical direction to a substrate plane, and (B) of FIG. 2 is a section diagram illustrating a configuration along a IIB-IIB line in (A) of FIG. 2.

FIG. 3 is a section diagram illustrating a step following (A) and (B) of FIG. 2.

FIG. 4 is a diagram illustrating a schematic configuration of a laser processor used for an irradiation step.

FIGS. 5A and 5B are a plan diagram and a section diagram illustrating a step following FIG. 3, respectively.

FIGS. 6A and 6B are a plan diagram and a section diagram illustrating a step following FIGS. 5A and 5B, respectively.

FIG. 7 is a section diagram illustrating a modification of FIG. 5B.

FIGS. 8A to 8C are section diagrams for explaining, in step order, a method of manufacturing an electronic element according to modification 1.

FIG. 9 is a section diagram illustrating, in step order, a method of manufacturing an electronic element according to a second embodiment of the disclosure.

FIGS. 10A to 10C are section diagrams illustrating steps following FIG. 9.

FIGS. 11A to 11C are section diagrams illustrating a modification of FIGS. 10A to 10C.

FIGS. 12A to 12C are section diagrams illustrating another modification of FIGS. 10A to 10C.

FIG. 13 is a section diagram illustrating a configuration of organic TFT as an electronic element according to a third embodiment of the disclosure.

FIG. 14 is a section diagram of the organic TFT having a cavity.

FIG. 15 is a plan diagram showing the organic TFTs illustrated in FIG. 13 arranged in a 2-by-2 matrix.

FIG. 16 is a section diagram along a XVI-XVI line in FIG. 15.

FIG. 17 is a section diagram along a XVII-XVII line in FIG. 15.

FIG. 18 is a section diagram illustrating a configuration of a major part of a liquid crystal display device as an application example of the organic TFT.

FIG. 19 is a diagram illustrating a circuit configuration of the liquid crystal display device illustrated in FIG. 18.

FIG. 20 is a section diagram illustrating a configuration of a major part of an organic EL display device as an application example of the organic TFT.

FIG. 21 is a diagram illustrating a circuit configuration of the organic EL display device illustrated in FIG. 20.

FIG. 22 is a section diagram illustrating a configuration of a major part of an electronic paper display device as an application example of the organic TFT.

FIG. 23 is a section diagram illustrating a configuration of an organic thin-film solar cell as an electronic element according to a fourth embodiment of the disclosure.

FIG. 24 is a section diagram illustrating a configuration of a flexible printed circuit board as an electronic element according to a fifth embodiment of the disclosure.

FIG. 25 is a section diagram illustrating a configuration of a touch panel as an electronic element according to a sixth embodiment of the disclosure.

FIGS. 26A and 26B are a plan diagram and a section diagram for explaining Example 1 according to the disclosure in step order.

FIG. 27 is a section diagram illustrating a step following FIGS. 26A and 26B.

FIG. 28 is a section diagram illustrating a step following FIG. 27.

FIG. 29 is a SEM photograph illustrating a section of the Example 1.

FIG. 30 is a copy of FIG. 29.

FIG. 31 is a SEM photograph illustrating a section of Example 2 of the disclosure.

FIG. 32 is a copy of FIG. 31.

### DETAILED DESCRIPTION OF EMBODIMENTS

Hereinafter, embodiments of the disclosure will be described in detail with reference to drawings. Description is made in the following order. First, a manufacturing method of an embodiment of the disclosure is described with a case, as an example, that short-circuit between two lines is repaired, in each of first and second embodiments. Next, description is made on an example where the manufacturing method of the embodiment of the disclosure is applied to a specific electronic element, in each of third to sixth embodiments.

1. First Embodiment (Example of Repairing In-Layer Short-Circuit)

2. Second Embodiment (Example of Repairing Interlayer Short-Circuit)

3. Third Embodiment (Organic TFT)

4. Application Example of Organic TFT

5. Fourth Embodiment (Organic Thin-Film Solar Cell)

6. Fifth Embodiment (Flexible Printed Circuit Board)

7. Sixth Embodiment (Touch Panel)

8. Examples

### First Embodiment

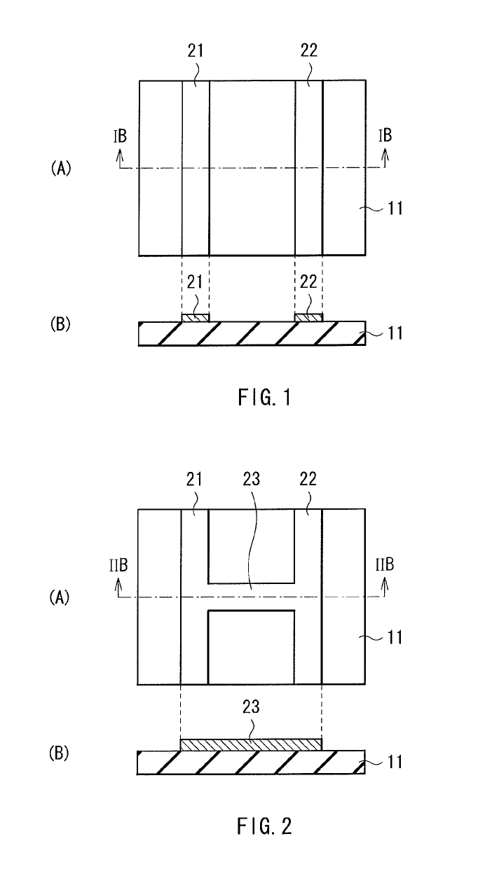

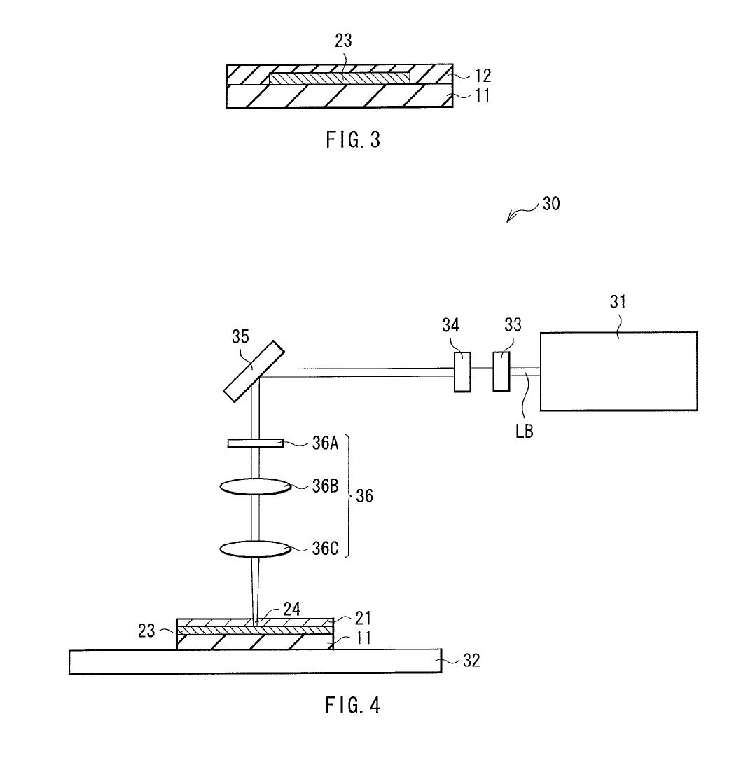

FIGS. 1 to 7 illustrate a method of manufacturing an electronic element according to a first embodiment of the disclosure in step order. In the manufacturing method, two wiring layers 21 and 22 are formed in one layer on a substrate 11, and a short-circuit portion 23 between the wiring layers 21 and 22, namely, in-layer short-circuit is repaired.

### (Wiring Layer Formation Step)

First, two parallel, linear wiring layers 21 and 22 are formed in one layer on the substrate 11 as illustrated in FIG. 1. Various substrates are properly used for the substrate 11 depending on applications. For example, a substrate including an organic insulating material such as plastic substrate, a glass substrate, or a metal substrate may be used. The substrate 11 may be configured of two or more materials of the above materials. When the substrate 11 includes a conductive material such as metal, a buffer layer (not shown) may be provided for insulation between the substrate 11 and the wiring layers 21 and 22.

A material of the wiring layers 21 and 22 includes, for example, a metal material such as gold, silver, copper, aluminum, titanium, or molybdenum, a conductive carbon material such as carbon nanotube or graphene, or a transparent electrode including ITO (Indium Tin Oxide) or FTO (fluorine-doped Tin Oxide). The wiring layers 21 and 22 are deposited by a sputtering method, an evaporation method, a plating method, or a coating method using nano-particles, and patterned by a photolithography process.

### (Organic Insulating Layer Formation Step)

The wiring layers 21 and 22 are electrically insulated from each other in a normal state as illustrated in FIG. 1. However, a short-circuit portion (in-layer short-circuit) 23 may be formed between the wiring layers 21 and 22 due to failure in a deposition step of the wiring layers 21 and 22, as illustrated in FIG. 2. In such a case, the wiring layers 21 and 22 are electrically short-circuited to each other, causing abnormality in a circuit. It is therefore necessary to detect the short-circuit portion 23 by optical inspection or the like, and cut or remove the detected portion 23 by laser processing to restore the circuit to the normal state.

The short-circuit portion 23 is preferably cut or removed by laser processing after forming an organic insulating layer 12 on the substrate 11 having the wiring layers 21 and 22 formed thereon. This is because when the short-circuit portion 23 is laser-processed in a state of FIG. 2 where the wiring layers 21 and 22 are exposed, rising of a processed end or debris is formed, causing in-layer short-circuit.

Inspection for detecting the short-circuit portion 23 may be performed either before or after a deposition step of the organic insulating layer 12.

The organic insulating layer 12 is formed by coating using a method of die coating, slit coating, spin coating, gravure coating, inkjet coating, or the like using an organic material of a polyacrylate series, a polystyrene series, a polyamide series, a polyimide series, an epoxy series, a novolac series, a fluorine series, or the like.

### (Laser Processor)

FIG. 4 illustrates a schematic configuration of a laser processor 30 used for cutting or removing the short-circuit portion 23. The laser processor 30 has, for example, a laser oscillator 31 generating a laser beam LB and a transfer stage 32 for setting the substrate 11. The substrate 11, having the wiring layer 21 and the organic insulating layer 12 formed thereon, is set on the transfer stage 32 with a short-circuit-portion 23 side facing upward. For example, a shutter 33, an intensity attenuator 34, a mirror 35, and a mask imaging optics 36 are disposed as a laser processing optics in this order from a laser oscillator 31 side on a path of the laser beam LB between the laser oscillator 31 and the transfer stage 32. The mask imaging optics 36 has, for example, a mask 36A, a tube lens 36B, and an imaging lens 36C in this order from a mirror 35 side.

For the laser oscillator 31, titanium sapphire femtosecond laser; erbium-doped femtosecond fiber laser, picosecond laser, or nanosecond laser; ytterbium-doped femtosecond fiber laser, picosecond laser, or nanosecond laser; Nd:YVO4 nanosecond laser or picosecond laser; Nd:YAG nanosecond laser; or Nd:YLF nanosecond laser or picosecond laser may be used. For spatial intensity distribution shaping of the laser beam LB, the mask imaging optics 36 illustrated in FIG. 4 may be used, or an optical fiber or a spatial phase modulator may be used instead. Alternatively, the laser beam LB from the laser oscillator 31 may be directly condensed by a lens without imaging.

In the laser processor 30, for example, the laser beam LB outputted from the laser oscillator 31 is condensed on the short-circuit portion 23 on the substrate 11 set on the transfer stage 32 through the shutter 33, the intensity attenuator 34, the mirror 35, and the mask imaging optics 36 (the mask 36A, the tube lens 36B, and the imaging lens 36C).

### (Irradiation Step)

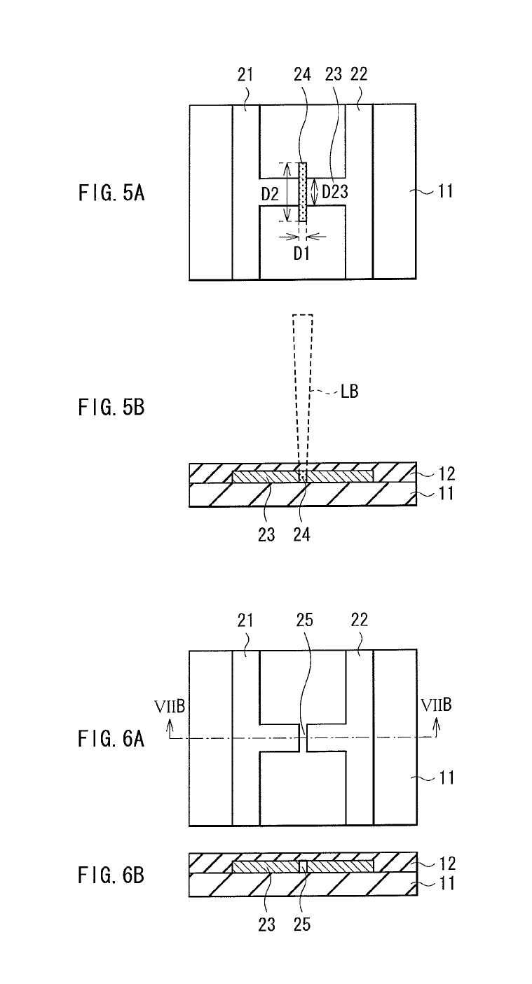

After the organic insulating layer 12 is formed, the short-circuit portion 23 is irradiated through the layer 12 with a laser beam LB having a wavelength transmissive through the layer 12, for example, using the laser processor shown in FIG. 4, as illustrated in FIGS. 5A and 5B. While the organic insulating layer 12 and the substrate 11 are in contact with tops and bottoms of the wiring layers 21 and 22 and of the short-circuit portion 23, the laser beam LB having the wavelength transmissive through the layer 12 is used, allowing the laser beam LB to arrive at the portion 23 through the layer 12, and consequently the short-circuit portion 23 may be selectively laser-processed.

This causes the short-circuit portion 23 to disappear from a laser-irradiated region 24, leading to recovery of insulation between the wiring layers 21 and 22, as illustrated in FIG. 6A. In addition, while the organic insulating layer 12 and the substrate 11 in contact with the top and bottom of the short-circuit portion 23 are still left, a cavity 25 is formed in the laser-irradiated region 24 (a portion where the short-circuit portion 23 has disappeared) as illustrated in FIG. 6B. The cavity 25 corresponds to a space formed in the same layer as the wiring layers 21 and 22, which is enclosed by the wiring layers 21 and 22, and the organic insulating layer 12 and the substrate 11 in contact with the tops and bottoms of the wiring layers 21 and 22. The cavity 25 may be found by cross-sectional observation using an optical microscope or an electron microscope. Constitutional materials of the short-circuit portion 23 that has disappeared gather in areas near ends of the cavity 25, or diffuse into the organic insulating layer 12 or the substrate 11. In FIGS. 5A and 6A, the organic insulating layer 12 is omitted to be shown.

In contrast, when the organic insulating layer 12 is deposited after the short-circuit portion 23 is removed by laser processing as in the past, the cavity 25 is not formed.

In this way, the short-circuit portion 23 is irradiated through the organic insulating layer 12 with the laser beam LB having the wavelength transmissive through the layer 12. This causes the laser-irradiated region 24 of the portion 23 to be removed while suppressing an effect of the laser beam on the layer 12 or substrate 11 in contact with the tops or bottoms of the wiring layers 21 and 22 having the portion 23, so that the short-circuit portion 23 is insulated and repaired. Moreover, unlike a method in the past, where the organic insulating layer 12 is formed after irradiation of the laser beam LB, irradiation of the laser beam LB is performed in a state where the organic insulating layer 12 is formed on the wiring layers 21 and 22 having the short-circuit portion 23, which reduces a possibility that a structure such as rising of a processed end or debris breaks through the layer 12. Accordingly, when another wiring layer is formed on the organic insulating layer 12, occurrence of interlayer short-circuit may be avoided.

The wavelength of the laser beam LB is preferably in a visible or near-infrared range. This is because if a wavelength in an ultraviolet or infrared range is used, the laser beam LB may be absorbed by a material of the organic insulating layer 12 or of the substrate 11.

A pulse laser beam having a pulse width of less than 100 ns is preferably used for the laser beam LB. The reason for this is that since a level of a thermal effect in laser processing is proportional to a square root of pulse width of a laser beam, too long pulse width induces a thermally bad effect such as excessive melting of a region near the laser-irradiated region 24, making it difficult to repair the short-circuit portion 23. Irradiation of the laser beam LB may be performed in a single shot (the number of shots: 1 pulse), or may be repeatedly performed with a repetition frequency of less than 1 MHz (the number of shots: multiple pulses). The repetition frequency of less than 1 MHz is used, making it possible to avoid a heat accumulation effect between pulses.

Intensity of the condensed laser beam LB is preferably equal to or more than a processing threshold of the wiring layers 21 and 22, and less than a processing threshold of the organic insulating layer 12 or the substrate 11. This leads to selective processing of wiring layers 21 and 22. When intensity of the laser beam LB is insufficient, an unprocessed portion remains, making it difficult to repair the short-circuit portion 23. When the intensity is excessively high, the organic insulating layer 12 or the substrate 11 is damaged. Irradiation is therefore performed with a condensing intensity enabling only the short-circuit portion 23 to be selectively processed. The processing threshold is hard to be simply determined since the threshold depends on a material or thickness of the wiring layer 21 or 22 or a material or thickness of the organic insulating layer 12. However, when peak field intensity of the laser beam LB is more than about 10¹³ W/cm², laser processing of the layer 12 starts due to multiple photon absorption, and therefore the peak field intensity at a processing point is less than 10¹³ W/cm². To make back calculation based on this, for example, when pulse width of the laser beam LB is 100 fs, peak fluence at a processing point is preferably less than 1 J/cm².

Widths D1 and D2 of the laser-irradiated region 24 are adjusted in such a manner that part or all of the short-circuit portion 23 is irradiated with the laser beam LB. In such adjustment, width D1 of the region 24 (length D1 of the portion 23 in an extending direction) is preferably shorter than width D23 of the portion 23. The width D1 of the region 24 is made short as much as possible, so that volume of a removed material of the portion 23 is decreased, making it possible to reduce rising of the organic insulating layer 12 deposited on the portion 23. However, even if the width D1 of the region 24 is not significantly reduced, the portion 23 may be repaired. In addition, even if the width D1 is tried to be reduced to the utmost, since the laser beam is gradually hard to be correctly condensed due to a diffraction limit, a lower limit of the width D1 is preferably approximately equal to a wavelength of the laser beam LB being used. The same is true of the width D2 of the region 24 (length D2 of the portion 23 in a width direction).

Width D2 of the laser-irradiated region 24 is preferably equal to or larger than the width D23 of the short-circuit portion 23. When the width D2 of the region 24 is shorter than the width D23 of the portion 23, an unprocessed portion remains, making it difficult to repair the short-circuit portion 23.

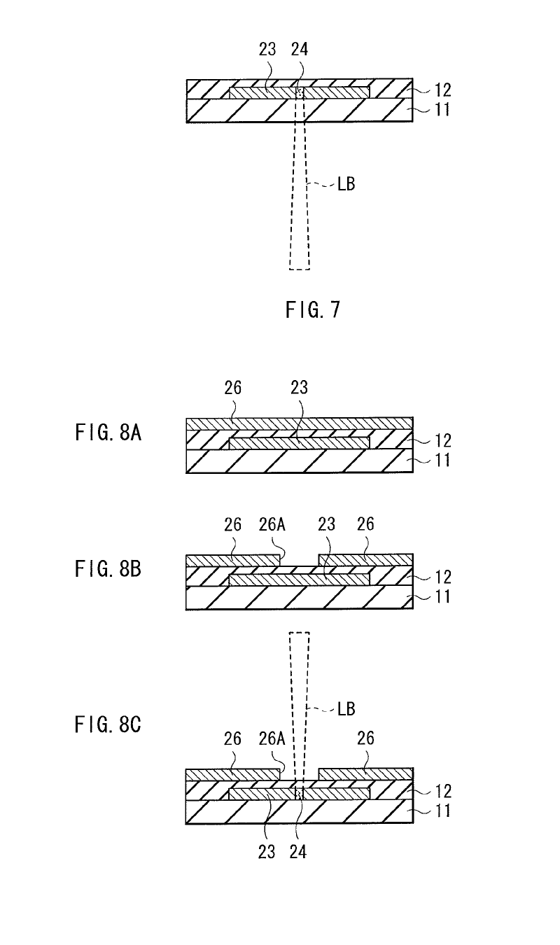

FIGS. 5A and 5B and FIGS. 6A and 6B are shown to describe a case where the short-circuit portion 23 is irradiated through the organic insulating layer 12 with the laser beam LB having the wavelength transmissive through the layer 12. However, even if the short-circuit portion 23 is irradiated through the substrate 11 with a laser beam LB having a wavelength transmissive through the substrate 11 as illustrated in FIG. 7, the portion 23 may be selectively cut or removed by laser processing in the same way as above, and a cavity 25 as in FIG. 6B may be thus formed. In such a case, an incident surface of the laser beam LB corresponds to a back surface of the substrate 11 contrary to that in FIG. 5B.

In this way, in the embodiment, the organic insulating layer 12 is formed on the wiring layers 21 and 22, and then the short-circuit portion 23 between the wiring layers 21 and 22 is irradiated through the layer 12 with the laser beam LB having the wavelength transmissive through the layer 12, or the portion 23 is irradiated through the substrate 11 with the laser beam LB having the wavelength transmissive through the substrate 11. This enables the short-circuit portion 23 between the wiring layers 21 and 22 to be insulated and repaired in a simple process although the short-circuit portion has been hardly repaired due to rising of a processed end or debris in the past, and furthermore enables a manufacturing yield to be improved. In addition, when an upper wiring layer three-dimensionally crosses the short-circuit portion 23 with the organic insulating layer 12 in between, interlayer short-circuit may be avoided.

### (Modification 1)

While the embodiment has been described with a case where the wiring layers 21 and 22 are formed in one layer on the substrate and the organic insulating layer 12 is formed on the wiring layers 21 and 22, an upper wiring layer 26 may be further provided on the layer 12 as illustrated in FIG. 8A. In either case, the laser beam LB needs to arrive at the short-circuit portion 23. For example, when the upper wiring layer 26 is previously provided on the layer 12 and therefore the short-circuit portion 23 between the wiring layers 21 and 22 is hardly irradiated with the laser beam LB, the wiring layer 26 may be partially removed by laser processing to form an opening 26A as a path of the laser beam LB as illustrated in FIG. 8B, allowing, through the opening 26A, subsequent laser processing of the short-circuit portion 23 between the lower wiring layers 21 and 22 to be performed as illustrated in FIG. 8C.

### Second Embodiment

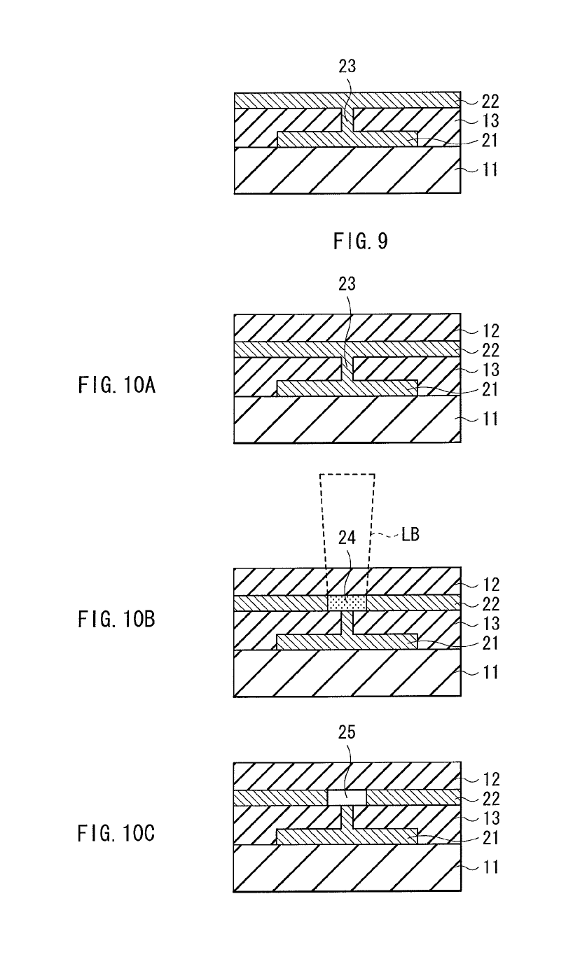

FIGS. 9 and FIGS. 10A to 10C illustrate, in step order, a method of manufacturing an electronic element according to a second embodiment of the disclosure. Two wiring layers 21 and 22 are formed in different layers with an organic insulating layer 13 in between on a substrate 11, and a short-circuit portion 23 between the wiring layers 21 and 22, namely, interlayer short-circuit is repaired.

### (Wiring Layer Formation Step)

First, a wiring layer 21, the organic insulating layer 13, and the wiring layer 22 are formed in this order on the substrate 11 as illustrated in FIG. 9. Respective materials or deposition methods of the substrate 11 and the wiring layers 21 and 22 are the same as those in the first embodiment. A material and a deposition method of the organic insulating layer 13 are the same as those of the organic insulating layer 12 in the first embodiment.

### (Organic Insulating Layer Formation Step)

After the wiring layers 21 and 22 are formed, the short-circuit portion 23 is detected by optical inspection or the like, and an organic insulating layer 12 is formed on the wiring layer 22 as illustrated in FIG. 10A, as in the first embodiment. A material and a deposition method of the organic insulating layer 12 are the same as those in the first embodiment. Inspection for detecting the portion 23 may be performed either before or after a deposition step of the organic insulating layer 12.

### (Irradiation Step)

After the organic insulating layer 12 is formed, the short-circuit portion 23 is irradiated through the layer 12 with a laser beam LB having a wavelength transmissive through the layer 12, for example, using the laser processor shown in FIG. 4 in the first embodiment, as illustrated in FIG. 10B. While the organic insulating layers 12 and 13 are in contact with tops and bottoms of the wiring layer 22 and of the short-circuit portion 23, the laser beam LB having the wavelength transmissive through the layer 12 is used, which allows the laser beam LB to arrive at the portion 23 through the layer 12, and consequently the short-circuit portion 23 may be selectively laser-processed.

This causes the short-circuit portion 23 to disappear from a laser-irradiated region 24, leading to recovery of insulation between the wiring layers 21 and 22, as illustrated in FIG. 10C. In addition, while the organic insulating layers 12 and 13 in contact with the tops and the bottoms of the wiring layer 22 and of the short-circuit portion 23 are still left, a cavity 25 is formed in the laser-irradiated region 24 (a portion where the short-circuit portion 23 has disappeared), as in the first embodiment.

In this way, the short-circuit portion 23 is irradiated through the organic insulating layer 12 with the laser beam LB having the wavelength transmissive through the layer 12. This causes the laser-irradiated region 24 of the short-circuit portion 23 to be removed while suppressing an effect of the laser beam on the organic insulating layer 12 or 13 in contact with the top or bottom of the wiring layer 22 having the portion 23, so that the short-circuit portion 23 is insulated. Moreover, unlike a method in the past, where the organic insulating layer 12 is formed after irradiation of the laser beam LB, irradiation of the laser beam LB is performed in a state where the organic insulating layer 12 is formed on the wiring layer 22 having the short-circuit portion 23, which reduces a possibility that a structure such as rising of a processed end or debris breaks through the layer 12. Accordingly, when another wiring layer is formed on the organic insulating layer 12, occurrence of interlayer short-circuit may be avoided.

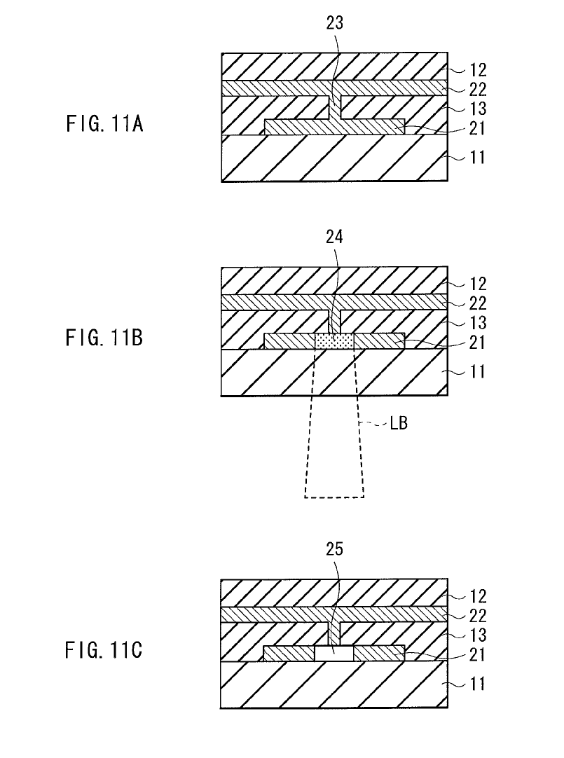

FIGS. 10A to 10C are shown to describe a case where the short-circuit portion 23 is irradiated through the organic insulating layer 12 with the laser beam LB having the wavelength transmissive through the layer 12. However, even if the short-circuit portion 23 is irradiated through the substrate 11 with a laser beam LB having a wavelength transmissive through the substrate 11, the wiring layer 21 under the portion 23 may be selectively cut or removed by laser processing and a cavity 25 may be thus formed in the same way as above, as illustrated in FIGS. 11A to 11C. In such a case, an incident surface of the laser beam LB corresponds to a back surface of the substrate 11 contrary to that in FIG. 10B. When irradiation of the laser beam LB is performed from a back side of the substrate 11 in this way, the organic insulating layer 12 need not be necessarily provided on the wiring layer 22.

In this way, in the embodiment, the organic insulating layer 12 is formed on the wiring layer 22, and then the short-circuit portion 23 is irradiated through the layer 12 with the laser beam LB having the wavelength transmissive through the layer 12, or the portion 23 is irradiated through the substrate 11 with the laser beam LB having the wavelength transmissive through the substrate 11. This enables the short-circuit portion 23 formed between the wiring layers 21 and 22 to be repaired in a simple process, and furthermore enables a manufacturing yield to be improved. In addition, when an upper wiring layer three-dimensionally crosses the short-circuit portion 23 with the organic insulating layer 12 in between, interlayer short-circuit may be avoided.

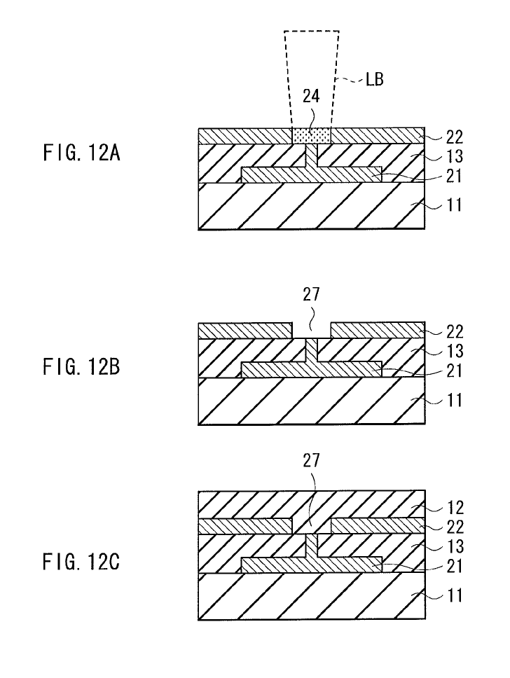

The embodiment has been described with a case where the organic insulating layer 12 is formed on the wiring layer 22 before irradiation of the laser beam LB. However, when the organic insulating layer 12 may be formed with a sufficiently large thickness, irradiation of the laser beam LB may be performed before forming the layer 12 with the wiring layer 22 and the short-circuit portion 23 being exposed, as illustrated in FIG. 12A. This is because large thickness of the organic insulating layer 12 reduces a possibility of subsequent occurrence of interlayer short-circuit due to a structure such as rising of a processed end or debris. In such a case, the laser-irradiated region 24 in the short-circuit portion 23 is removed by irradiation of the laser beam LB to form a cut portion 27 so that the wiring layers 21 and 22 are insulated from each other as illustrated in FIG. 12B, and then the organic insulating layer 12 is formed as illustrated in FIG. 12C. Here, the cut portion 27 is filled with the organic insulating layer 12 and therefore formation of the cavity 25 is prevented.

### Third Embodiment

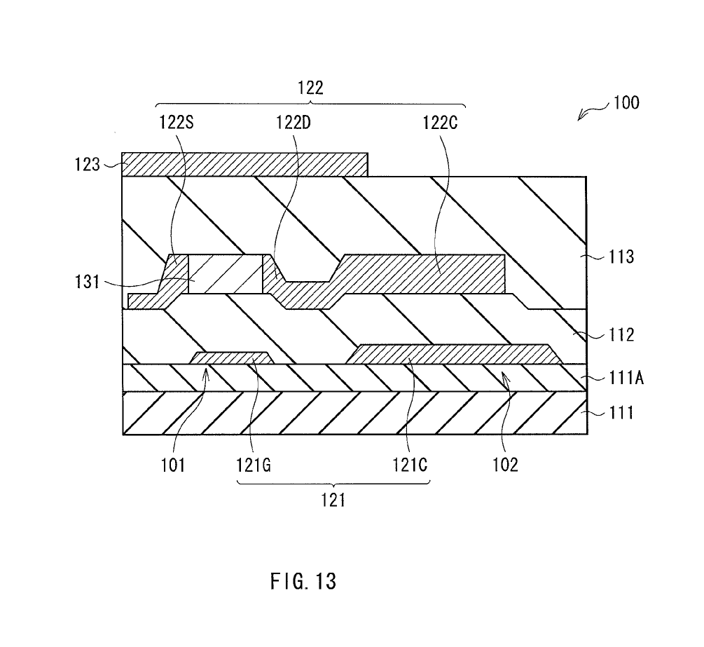

FIG. 13 illustrates a sectional configuration of an organic TFT as an electronic element according to a third embodiment of the disclosure. The organic TFT 100 is used for a liquid crystal display device, an organic EL display device, or an electronic display element such as a flexible electronic paper, and has a configuration where a buffer layer 111A, a lower metal layer 121, a gate insulating film 112, an organic semiconductor layer 131 and an upper metal layer 122, an interlayer insulating layer 113, and a top metal layer 123 are stacked in this order on a substrate 111. Here, each of the lower metal layer 121, the upper metal layer 122, and the top metal layer 123 corresponds to a specific example of “wiring layer” of the disclosure, and each of the gate insulating film 112 and the interlayer insulating layer 113 corresponds to a specific example of “organic insulating layer” of the disclosure.

The buffer layer 111A is configured of, for example, an organic material of a polyacrylate series, a polystyrene series, a polyamide series, a polyimide series, an epoxy series, a novolac series, or a fluorine series. The gate insulating film 112 and the interlayer insulating layer 113 are configured of, for example, the same material as that of the organic insulating layer 12 in the first embodiment. The lower metal layer 121, the upper metal layer 122, and the top metal layer 123 are configured of, for example, the same material as that of the wiring layer 21 or 22 in the first embodiment. The lower metal layer 121 includes a gate electrode 121G and a lower electrode 121C of a capacitor. The upper metal layer 122 includes a source electrode 122S, a drain electrode 122D, and an upper electrode 122C of the capacitor. The gate electrode 121G, the gate insulating film 112, the organic semiconductor layer 131, the source electrode 122S, and the drain electrode 122D collectively configure a TFT section 101. The lower electrode 121C and the upper electrode 122C collectively configure a capacitor section 102. The top metal layer 123 corresponds to, for example, a pixel electrode of an organic EL element described later.

In manufacturing of the organic TFT 100, one or more of the lower metal layer 121, the upper metal layer 122, and the top metal layer 123 are formed through the wiring layer formation step, the organic insulating layer formation step, and the irradiation step in the first or second embodiment.

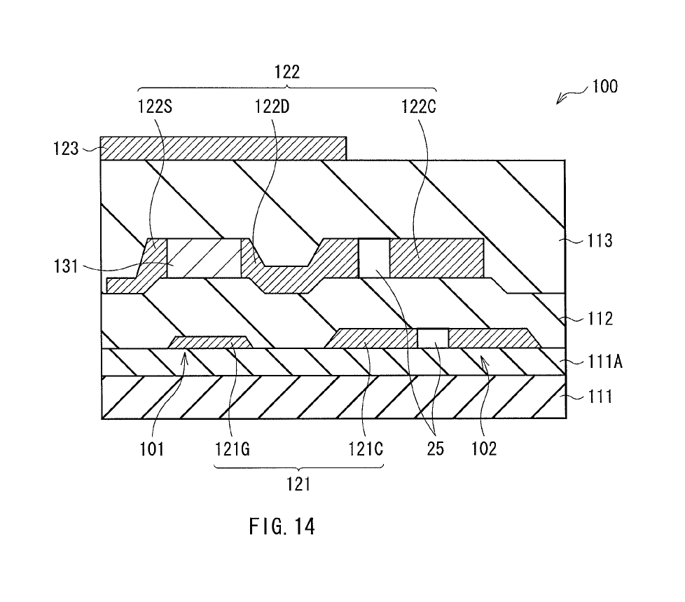

For example, the organic TFT 100 has a cavity 25 in the same layer as the lower metal layer 121 (for example, the lower electrode 121C of the capacitor section 102) or the upper metal layer 122 (for example, the upper electrode 122C of the capacitor section 102), as illustrated in FIG. 14. For example, the cavity 25 is formed by insulating and repairing a short-circuit portion 23, formed between layers of the lower electrode 121C and the upper electrode 122C of the capacitor section 102, through the wiring layer formation step, the organic insulating layer formation step, and the irradiation step in the second embodiment.

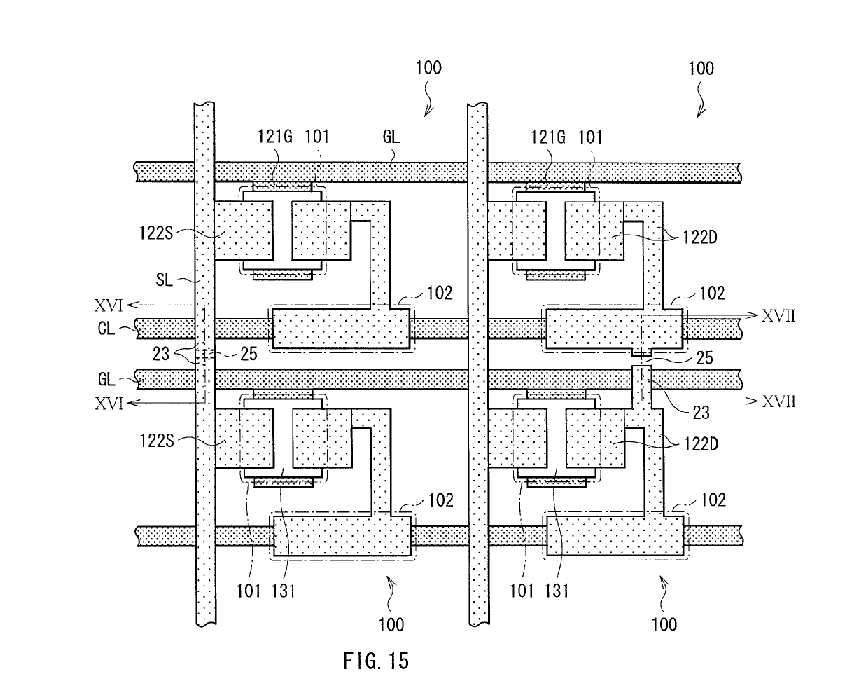

FIG. 15 illustrates a planar configuration where the organic TFTs 100 illustrated in FIG. 13 are arranged in a 2-by-2 matrix. The gate electrode 121G of each organic TFT 100 is connected to a scan line (gate line) GL in the same layer as the lower metal layer 121. The lower electrode 121C of the capacitor section 102 of each organic TFT 100 is connected to a capacitance line CL in the same layer as the lower metal layer 121. The source electrode 122S of each organic TFT 100 is connected to a signal line SL in the same layer as the upper metal layer 122.

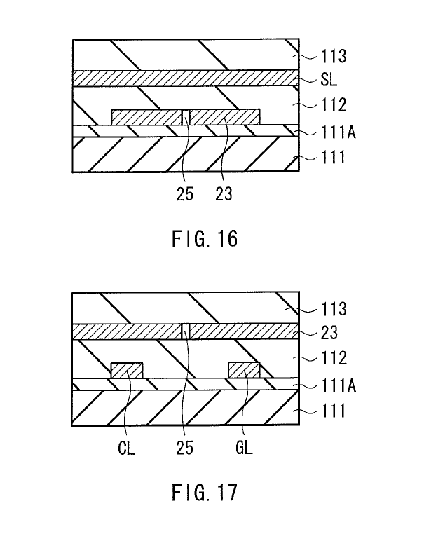

For example, the organic TFT 100 has a cavity 25 in the same layer as the scan line GL and the capacitance line CL, as illustrated in FIG. 16. For example, the cavity 25 is formed by insulating and repairing a short-circuit portion 23 (in-layer short-circuit) between the scan line GL and the capacitance line CL through the wiring layer formation step, the organic insulating layer formation step, and the irradiation step in the first embodiment.

In addition, for example, the organic TFT 100 has a cavity 25 in the same layer as the upper electrode 122C of the capacitor section 102 and the drain electrode 122D, as illustrated in FIG. 17. For example, the cavity 25 is formed by insulating and repairing a short-circuit portion 23 (in-layer short-circuit) between the upper electrode 122C of the capacitor section 102 and the drain electrode 122D through the wiring layer formation step, the organic insulating layer formation step, and the irradiation step in the first embodiment.

### Application Examples of Organic TFT

Next, application examples of the organic TFT 100 are described. For example, the organic TFT 100 may be applied to the following electronic units.

### Application Example 1 of Organic TFT, Liquid Crystal Display Device

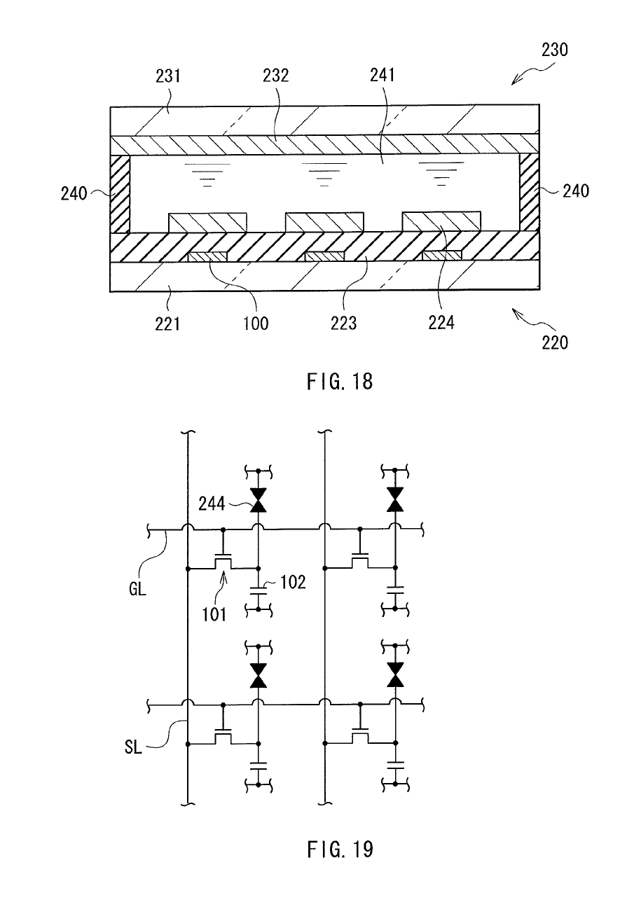

For example, the organic TFT 100 is applied to a liquid crystal display device. FIGS. 18 and 19 illustrate a sectional configuration and a circuit configuration of a major part of the liquid crystal display device, respectively. A device configuration (FIG. 18) and a circuit configuration (FIG. 19) described below are merely shown as an example, and the configurations may be appropriately modified.

The liquid crystal display device described herein is, for example, an active-matrix-drive transmissive liquid crystal display using the organic TFTs 100 as switching elements. In the liquid crystal display device, a liquid crystal layer 241 is enclosed between a drive substrate 220 and a counter substrate 230 as illustrated in FIG. 18. The liquid crystal display device may be not only of the transmissive type but also of a reflective type.

The drive substrate 220 includes, for example, the organic TFTs 100, a flattening insulating layer 223, and pixel electrodes 224 formed in this order on one surface of a support substrate 221, where the organic TFTs 100 and the pixel electrodes 224 are arranged in a matrix. The number of the organic TFTs 100 in a pixel may be one, or may be two or more. For example, FIGS. 18 and 19 illustrate a case that a pixel has one organic TFT 100 therein.

The support substrate 221 is formed of, for example, a transmissive material such as glass or plastic. The flattening insulating layer 223 is formed of, for example, an insulating resin material such as polyimide, and the pixel electrodes 224 are formed of, for example, a transmissive conductive material such as ITO. Each pixel electrode 224 is connected to the organic TFT 100 through a contact hole (not shown) provided through the flattening insulating layer 223.

For example, the counter substrate 230 includes a counter electrode 232 formed over the whole area of one surface of a support substrate 231. The support substrate 231 is formed of, for example, a transmissive material such as glass or plastic, and the counter electrode 232 is formed of, for example, a transmissive conductive material such as ITO.

The drive substrate 220 and the counter substrate 230 are disposed in such a manner that the pixel electrodes 224 and the counter electrode 232 are opposed to each other with the liquid crystal layer 241 in between, and attached to each other with a seal material 240. A type of liquid crystal molecules contained in the liquid crystal layer 241 may be optionally selected.

In addition, the liquid crystal display device may include other components such as a retardation film, a polarizing plate, an alignment film, and a backlight unit, any of which is not shown.

For example, a circuit for driving the liquid crystal display device includes the organic TFTs 100 (each including the TFT section 101 and the capacitor section 102) and liquid crystal display elements 244 (element sections each including the pixel electrode 224, the counter electrode 232, and the liquid crystal layer 241). In the circuit, a plurality of signal lines SL are arranged in a row direction, and a plurality of scan lines GL are arranged in a column direction, and the organic TFTs 100 and the liquid crystal display elements 244 are disposed at respective crossing positions of the lines SL and GL. Respective connection objects of the source electrode, the gate electrode, and the drain electrode of the organic TFT 100 are not limited to those in an aspect illustrated in FIG. 19, and may be optionally changed. The signal line SL and the scan line GL are connected to a not-shown signal-line drive circuit, or data driver, and a not-shown scan-line drive circuit, or scan driver, respectively.

In the liquid crystal display device, the TFT section 101 of the organic TFT 100 selects a liquid crystal display element 244, and when an electric field is applied between the pixel electrode 224 and the counter electrode 232 of the element 244, an alignment state of the liquid crystal layer 241, or liquid crystal molecules, is changed depending on intensity of the electric field. Consequently, the amount of light transmission, or transmittance, is controlled depending on alignment states of the liquid crystal molecules, leading to display of a gradation image.

### Application Example 2 of Organic TFT, Organic EL Display Device

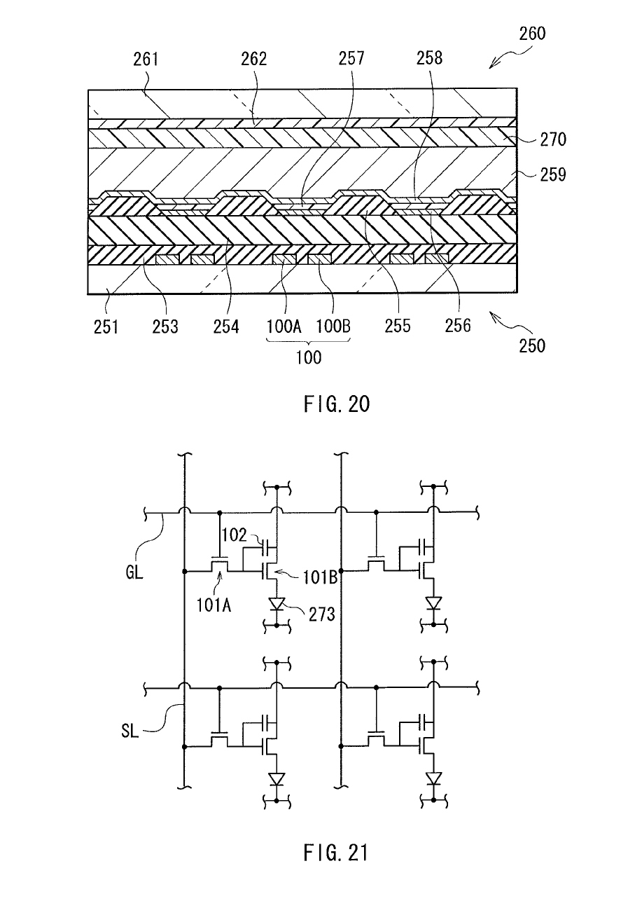

For example, the organic TFT 100 is applied to an organic EL display device. FIGS. 20 and 21 illustrate a sectional configuration and a circuit configuration of a major part of the organic EL display device, respectively. A device configuration (FIG. 20) and a circuit configuration (FIG. 21) described below are merely shown as an example, and the configurations may be appropriately modified.

The organic EL display device described herein is, for example, an active-matrix-drive organic EL display using the organic TFTs 100 as switching elements. The organic EL display device is configured by attaching a drive substrate 250 to a counter substrate 260 with an adhesion layer 270, e.g. a thermosetting resin, in between, and, for example, is of a top-emission type where light is emitted through the counter substrate 260.

The drive substrate 250 includes, for example, the organic TFTs 100, a protective layer 253, a flattening insulating layer 254, pixel separation insulating layers 255, pixel electrodes 256, organic layers 257, a counter electrode 258, and a protective layer 259 formed in this order on one surface of a support substrate 251. The organic TFTs 100, the pixel electrodes 256, and the organic layers 257 are arranged in a matrix. The number of the organic TFTs 100 in a pixel may be one, or may be two or more. For example, FIGS. 20 and 21 illustrate a case that a pixel has two organic TFTs 100 (selection organic TFT 100A and drive organic TFT 100B).

The support substrate 221 is formed of, for example, a glass or plastic material. Since light is extracted through the counter substrate 260 in the top emission type, the support substrate 251 may be formed of either a transmissive or non-transmissive material. The protective layer 253 is formed of, for example, a polymer material such as polyvinyl alcohol (PVA) or polyparaxylene. The flattening insulating layer 254 and the pixel separation insulating layers 255 are formed of, for example, an insulative resin material such as polyimide. The pixel separation insulating layers 255 are preferably formed of, for example, a photosensitive resin material moldable by optical patterning or reflow in order to simplify a formation process and to form the layer 255 into a desired shape. If the protective layer 253 provides sufficient flatness, the flattening insulating layer 254 may be omitted.

The pixel electrode 256 is formed of, for example, a reflective material such as aluminum, silver, titanium, or chromium, and the counter electrode 258 is formed of, for example, a transmissive conductive material such as ITO or IZO. However, the counter electrode 258 may be formed of a transmissive metal material such as calcium (Ca) or an alloy thereof, or a transmissive organic conductive material such as PEDOT. The organic layer 257 contains a light-emitting layer emitting light of red, green, or blue, and may have a stacked structure including a hole transport layer and an electron transport layer as necessary. A formation material of the light-emitting layer may be optionally selected depending on a color of light to be emitted. While the pixel electrodes 256 or the organic layers 257 are arranged in a matrix while being separated by the pixel separation insulating layers 255, the counter electrode 258 continuously extends while being opposed to the pixel electrodes 256 with the organic layers 257 in between. The protective layer 259 is formed of, for example, a light-transmissive dielectric material such as silicon nitride (SiN). Each pixel electrode 256 is connected to the organic TFT 100 through a contact hole (not shown) provided through the protective layer 253 and through the flattening insulating layer 254.

For example, the counter substrate 260 includes a color filter 262 over the whole area of one surface of a support substrate 261. The support substrate 261 is formed of, for example, a transmissive material such as glass or plastic, and the color filter 262 has a plurality of color regions corresponding to colors of light emitted by the organic layer 257. However, the color filter 262 may be eliminated.

For example, a circuit for driving the organic EL display device includes the organic TFTs 100 (selection organic TFTs 100A and driving organic TFTs 100B) and organic EL display elements 273 (element sections each including the pixel electrode 256, the organic layer 257, and the counter electrode 258). In the circuit, the organic TFTs 100 and the organic EL display elements 273 are disposed at respective crossing positions of signal lines 271 and scan lines 272. Respective connection objects of a source electrode, a gate electrode, and a drain electrode of each of the selection organic TFT 100A and the driving organic TFT 100B are not limited to those in an aspect illustrated in FIG. 21, and may be optionally changed.

In the organic EL display device, for example, when the TFT section 101A of the selection organic TFT 100A selects an organic EL display element 273, the element 273 is driven by the TFT section 101B of the driving organic TFT 100B. This causes an electric field to be applied between the pixel electrode 256 and the counter electrode 258, leading to light emission of the organic layer 257. Here, for example, respective three organic-EL-display elements 273 adjacent to one another emit light of red, green, and blue. Composite light of the three kinds of color light is outputted to the outside through the counter substrate 260, leading to display of a gradation image.

The organic EL display device may be not only of the top emission type, but also of a bottom emission type where light is outputted through the driving substrate 250, or of a dual emission type where light is outputted through both the driving substrate 250 and the counter substrate 260. In such a case, between the pixel electrode 256 and the counter electrode 258, an electrode on a light-emission side is formed of a transmissive material, and another electrode on a non-light-emission side is formed of a reflective material.

### Application Example 3 of Organic TFT, Electronic Paper Display Device

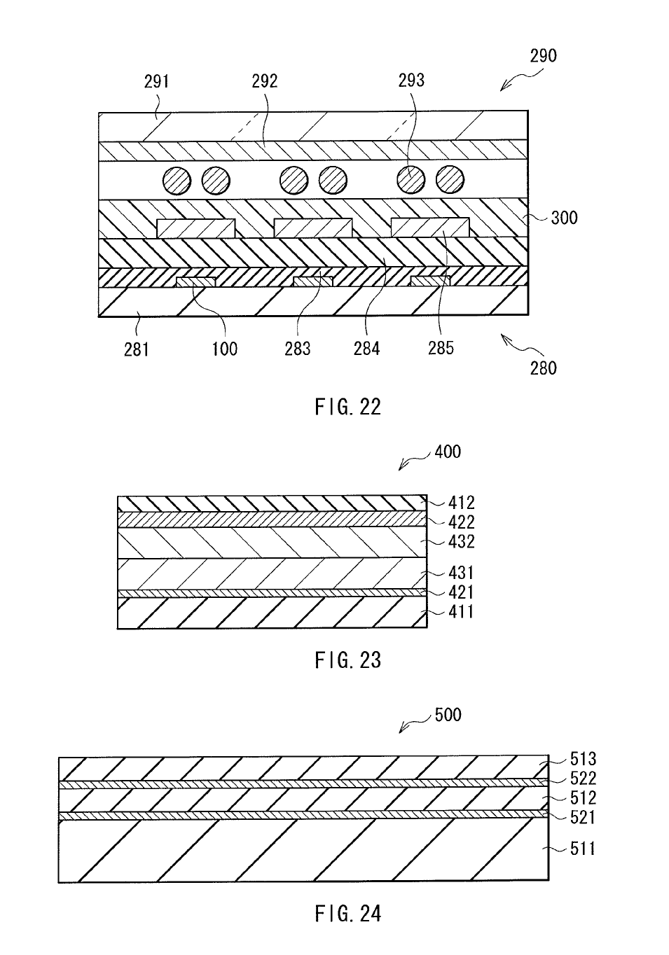

For example, the organic TFT 100 is applied to an electronic paper display device. FIG. 22 illustrates a sectional configuration of the electronic paper display device. A device configuration (FIG. 22) described below and a circuit configuration described with reference to FIG. 19 are merely shown as an example, and the configurations may be appropriately modified.

The electronic paper display device described herein is, for example, an active-matrix-drive electronic paper display using the organic TFTs 100 as switching elements. The electronic paper display device is configured by attaching a drive substrate 280 to a counter substrate 290, having a plurality of electrophoresis elements 293, with an adhesion layer 300 in between.

The drive substrate 280 includes, for example, the organic TFTs 100, a protective layer 283, a flattening insulating layer 284, and pixel electrodes 285 formed in this order on one surface of a support substrate 281, where the organic TFTs 100 and the pixel electrodes 285 are arranged in a matrix. The support substrate 281 is formed of, for example, a glass or plastic material. The protective layer 283 and the flattening insulating layer 284 are formed of, for example, an insulating resin material such as polyimide, and the pixel electrodes 285 are formed of, for example, a metal material such as silver. Each pixel electrode 285 is connected to the organic TFT 100 through a contact hole (not shown) provided through the protective layer 283 and through the flattening insulating layer 284. If the protective layer 283 provides sufficient flatness, the flattening insulating layer 284 may be omitted.

For example, the counter substrate 290 includes a counter electrode 292 and a layer containing the plurality of electrophoresis elements 293 stacked in this order on one surface of a support substrate 291, where the counter electrode 292 is formed over the whole area of the surface. The support substrate 291 is formed of, for example, a transmissive material such as glass or plastic material, and the counter electrode 292 is formed of, for example, a transmissive conductive material such as ITO. For example, the electrophoresis element 293 is configured by dispersing charged particles in an insulative liquid, and enclosing the liquid within a microcapsule. The charged particles include, for example, black particles such as graphite particles and white particles such as titanium oxide particles.

A circuit for driving the electronic paper display device has, for example, the same configuration as that of the circuit of the liquid crystal display device illustrated in FIG. 19. The circuit of the electronic paper display device includes organic TFTs 100 and electronic paper display elements (element sections each including the pixel electrode 285, the counter electrode 292, and the electrophoresis element 293) in place of the organic TFTs 100 and the liquid crystal display element 44, respectively.

In the electronic paper display device, the organic TFT 100 selects an electronic paper display element, and when an electric field is applied between the pixel electrode 285 and the counter electrode 292 of the element, the black or white particles in the electrophoresis element 293 are attracted to the counter electrode 292 depending on the electric field. This results in expression of contrast by the black and white particles, leading to display of a gradation image.

### Fourth Embodiment

FIG. 23 illustrates a sectional configuration of an organic thin-film solar cell as an electronic element according to a fourth embodiment of the disclosure. The organic thin-film solar cell 400 has a configuration where a transparent conductive layer 421, a p-type organic semiconductor layer 431, an n-type organic semiconductor layer 432, a metal electrode layer 422, and an organic insulating substrate 412 are stacked in this order on a substrate 411. Here, each of the transparent conductive layer 421 and the metal electrode layer 422 corresponds to a specific example of “wiring layer” of the disclosure, and the organic insulating substrate 412 corresponds to a specific example of “organic insulating layer” of the disclosure.

In manufacturing of the organic thin-film solar cell 400, one or both of the transparent conductive layer 421 and the metal electrode layer 422 are formed through the wiring layer formation step, the organic insulating layer formation step, and the irradiation step in the first or second embodiment. Accordingly, the organic thin-film solar cell 400 has a cavity 25 in the same layer as one or both of the transparent conductive layer 421 and the metal electrode layer 422 (not shown in FIG. 23, see FIG. 6 or 10).

### Fifth Embodiment

FIG. 24 illustrates a sectional configuration of a flexible printed circuit board as an electronic element according to a fifth embodiment of the disclosure. The flexible printed circuit board 500 has a configuration where a plurality of (for example, two in FIG. 24) wiring layers 521 and 522 and organic insulating layers 512 and 513 are alternately stacked on a substrate 511.

In manufacturing of the flexible printed circuit board 500, one or both of the wiring layers 521 and 522 are formed through the wiring layer formation step, the organic insulating layer formation step, and the irradiation step in the first or second embodiment. Accordingly, the flexible printed circuit board 500 has a cavity 25 in the same layer as one or both of the wiring layers 521 and 522 (not shown in FIG. 24, see FIG. 6 or 10).

### Sixth Embodiment

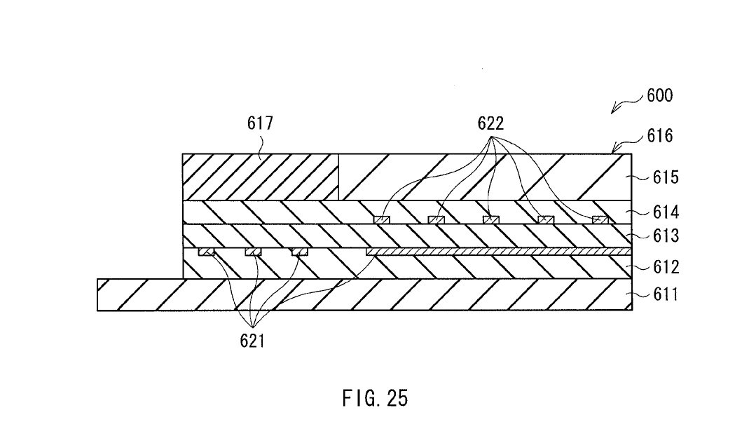

FIG. 25 illustrates a sectional configuration of a touch panel as an electronic element according to a sixth embodiment of the disclosure. The touch panel 600 has a configuration where a first insulating layer 612, a first transparent electrode 621, a dielectric sheet 613, a second transparent electrode 622, and a second insulating layer 614 are stacked in this order on a substrate 611. Each of the first and second transparent electrodes 621 and 622 has a large number of parallel stripe electrodes, and the two kinds of stripe electrodes are provided in directions orthogonal to each other with the dielectric sheet 613 in between. A cover sheet 615 is provided on a surface of the second insulating layer 614, and a surface of the cover sheet 615 corresponds to an operation surface 616. A shield member 617 is provided around the cover sheet 615. Here, each of the first and second transparent electrodes 621 and 622 corresponds to a specific example of “wiring layer” of the disclosure, and each of the first insulating layer 612, the dielectric sheet 613, and the second insulating layer 614 corresponds to a specific example of “organic insulating layer” of the disclosure.

In manufacturing of the touch panel 600, one or both of the first and second transparent electrodes 621 and 622 are formed through the wiring layer formation step, the organic insulating layer formation step, and the irradiation step in the first or second embodiment. Accordingly, the touch panel 600 has a cavity 25 in the same layer as one or both of the first and second transparent electrodes 621 and 622 (not shown in FIG. 25, see FIG. 6 or 10).

### EXAMPLES

Hereinafter, specific Examples of the disclosure are described. In the following Examples, one wiring layer 21 is formed on a substrate 11, and the wiring layer 21 is broken (cut) in the same way as in the first embodiment.

### Example 1

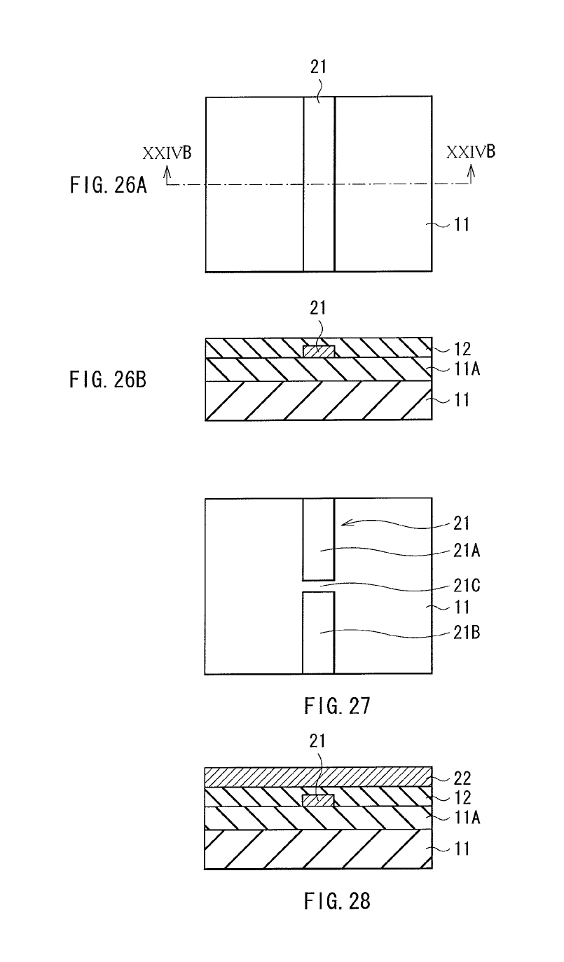

First, a buffer layer 11A, the wiring layer 21 including metal (100 nm in thickness), and an organic insulating layer 12 (800 nm in thickness) were formed in this order on the substrate 11 including a polymer, as illustrated in FIGS. 26A and 26B. Width of the wiring layer 21 was 15 μm.

The wiring layer 21 was irradiated with a laser beam LB (wavelength of 800 nm, pulse width of 200 fs, number of shots of 1 pulse, and irradiation spot size of 25-by-4 μm) using femtosecond laser from an organic insulating layer 12 side. As a result, the wiring layer 21 was cut at a central portion 21C and formed into two wiring layers 21A and 21B as illustrated in FIG. 27. A processed portion was observed using an optical microscope and an electron microscope, revealing that a top of the layer 21 was covered with an organic insulating layer 12, and only a laser-irradiated region in the layer 21 under the organic insulating layer 12 was selectively processed and formed into a cavity 25 (see FIG. 6B). In addition, the layer 12 was not damaged near the cavity in observation using the optical microscope and the electron microscope.

Next, a voltage of 10 V was applied between the wiring layers 21A and 21B to confirm an insulating state of a portion where the wiring layer 21 was removed by the laser processing. As a result, leakage current was less than 1 pA, showing that the wiring layer 21 was able to be broken by laser processing without damaging the organic insulating layer 12.

Then, a wiring layer 22 of 100 nm in thickness was deposited on the organic insulating layer 12 as illustrated in FIG. 28, and interlayer leakage current between the wiring layers 21 and 22 was measured. As a result, the interlayer leakage current was less than 10 pA even under voltage application of 100 V, showing that sufficient interlayer withstanding voltage was provided even after the laser processing.

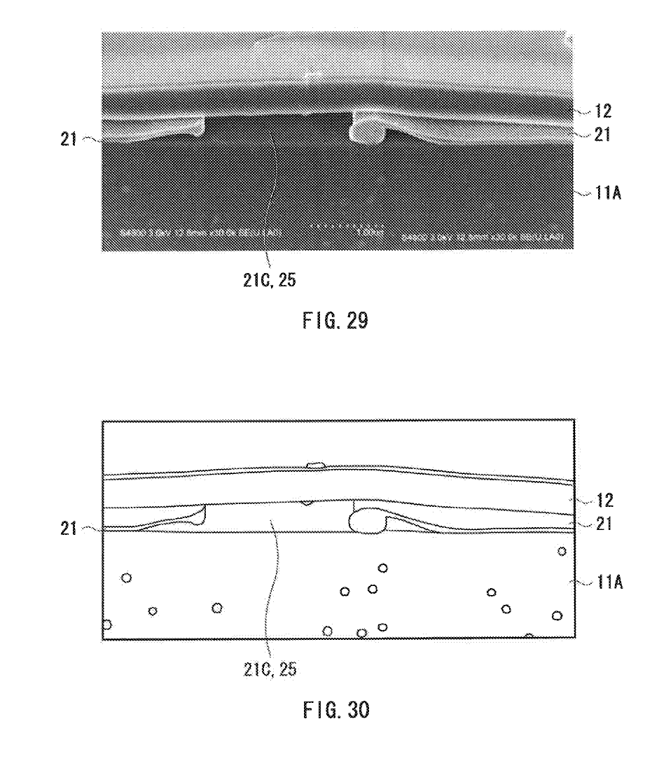

Furthermore, a cross section of the Example in a state of FIG. 27 was exposed using a focused ion beam for cross-sectional SEM (Electron Microscopy) observation. FIG. 29 illustrates a result of the SEM observation. FIG. 30 is a copy of FIG. 29. Metal disappears from a central portion 21C of the wiring layer 21 deposited on the buffer layer 11A and the cavity 25 is formed in the portion. Since a left end of the layer 21 has a round shape, metal initially existed in the portion 21C is believed to be moved due to thermal fusion or a shock wave. The organic insulating layer 12 is not damaged. In this way, laser irradiation is performed with appropriate laser intensity, making it possible to locally process only the inside wiring layer 21 to repair the short-circuit portion. In addition, no debris is typically formed in such a laser processing method since the organic insulating layer 12 is prevented from being damaged.

### Example 2

A buffer layer 11A, a wiring layer 21 including metal (100 nm in thickness), and an organic insulating layer 12 (800 nm in thickness) were formed in this order on a substrate 11 including a polymer, as in the Example 1. The wiring layer 21 was evaluated in the same way as the Example 1 using nanosecond laser (Nd:YAG laser, wavelength of 532 nm, 1 shot, and irradiation spot size of 25-by-4 μm) to verify an effect of pulse width.

First, a voltage of 10 V was applied between the wiring layers 21A and 21B in the state of FIG. 27 as in the Example 1. As a result, leakage current was less than 10 pA, showing that the wiring layer 21 was able to be broken even in the Example 2.

In addition, when a voltage of 100 V was applied between the wiring layers 21 and 22 in the state of FIG. 28 as in the Example 1, interlayer leakage current was less than 100 pA, showing that sufficient withstanding voltage was provided even after the laser processing.

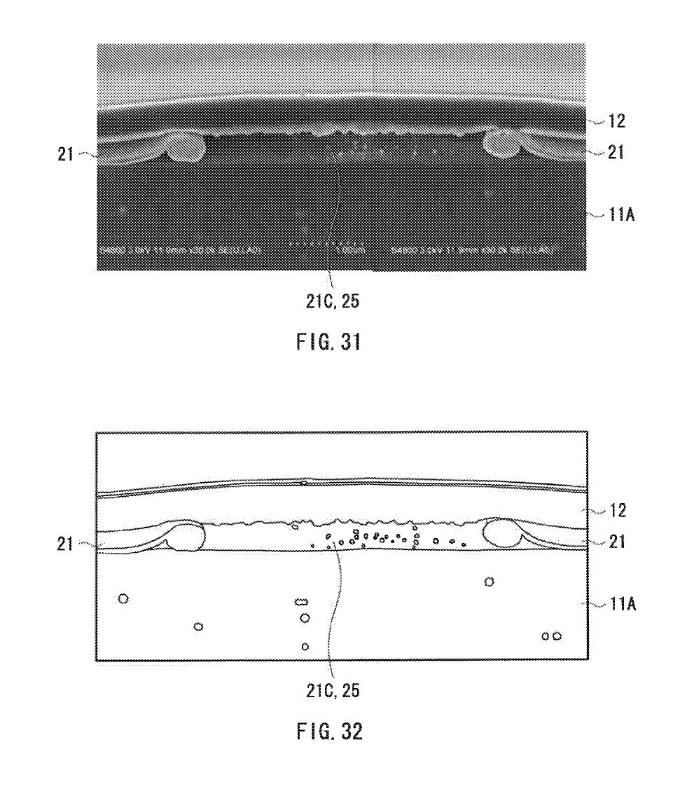

Furthermore, a portion selectively subjected to the laser processing was exposed using a focused ion beam for cross-sectional SEM observation as in the Example 1. FIG. 31 illustrates a result of the SEM observation. FIG. 32 is a copy of FIG. 31. While a central portion 21C that initially included the metal wiring layer on the buffer layer 11A disappears, the organic insulating layer 12 on the portion 21C still remains as in the Example 1. However, a lower surface of the layer 12 is somewhat damaged, and besides, certain damage or a residue of a metal wiring material is found near the central portion 21C on a surface of the buffer layer 11A unlike in the Example 1 using the femtosecond laser.

As a result of EDX analysis (Energy Dispersive X-ray spectroscopy) of a damaged region of the organic insulating layer 12, a metal material of the wiring layer 21 was detected, revealing that the material of the layer 21 was diffused in the layer 12. This is believed to be due to a thermal effect caused by a relatively long pulse width, which is likely to be disadvantageous from a viewpoint of long-term reliability of an electronic element. However, since an electric property necessary for repairing the short-circuit portion is obtained even in the Example 2 using the nanosecond laser, optimum pulse width can be selected comparing cost of manufacturing equipment to reliability of a device.

In other words, the wiring layer 21 is irradiated through the organic insulating layer 12 with a laser beam LB having a wavelength transmissive through the layer 12, allowing the layer 21 to be selectively processed (broken) while suppressing effects of the laser beam on the layer 12 or the buffer layer 11A in contact with a top or bottom of the layer 21.

While the disclosure has been described with the embodiments and the Examples hereinbefore, the disclosure is not limited to the embodiments and the Examples, and various modifications or alterations may be made. For example, while the embodiments have been described with a case where the cavity 25 remains, the cavity 25 may be eliminated, for example, by filling the cavity 25 with a resin material from a viewpoint of improving long-term reliability.

The present disclosure contains subject matter related to that disclosed in Japanese Priority Patent Application JP 2010-197985 filed in the Japan Patent Office on Sep. 3, 2010, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A method of manufacturing an electronic element for forming the electronic element including one or more wiring layers and an organic insulating layer stacked on a substrate, the method comprising:
a wiring layer formation step of forming the wiring layer on the substrate;
an organic insulating layer formation step of forming an organic insulating layer on the wiring layer; and
an irradiation step of irradiating a short-circuit portion of the wiring layer through the organic insulating layer with a laser beam having a wavelength transmissive through the organic insulating layer.

2. The method of manufacturing an electronic element according to claim 1, wherein a laser-beam-irradiated region in the short-circuit portion is removed to form a cavity.

3. The method of manufacturing an electronic element according to claim 2, wherein another wiring layer is formed on the organic insulating layer and
a region of the another wiring layer opposed to the short-circuit portion is selectively removed, between the organic insulating layer formation step and the irradiation step.

4. The method of manufacturing an electronic element according to claim 3, wherein condensing density of the laser beam is equal to or more than a processing threshold of the wiring layer and less than a processing threshold of the organic insulating layer or the substrate.

5. The method of manufacturing an electronic element according to claim 4, wherein a pulse laser beam having a pulse width of less than 100 ns is used as the laser beam.

6. The method of manufacturing an electronic element according to claim 5, wherein irradiation of the laser beam is performed in a single shot or repeatedly performed with a repetition frequency of less than 1 MHz.

7. The method of manufacturing an electronic element according to claim 6, wherein length of the laser-beam-irradiated region in an extending direction of the short-circuit portion is shorter than width of the short-circuit portion.

8. The method of manufacturing an electronic element according to claim 1, wherein an organic thin film transistor is formed to include a lower metal layer as the wiring layer, a gate insulating film as the organic insulating layer, an organic semiconductor layer, an upper metal layer as the wiring layer, an interlayer insulating layer as the organic insulating layer, and a top metal layer as the wiring layer stacked in this order on the substrate, and
one or more of the lower metal layer, the upper metal layer, and the top metal layer are formed through the wiring layer formation step, the organic insulating layer formation step, and the irradiation step.

9. The method of manufacturing an electronic element according to claim 1, wherein a flexible printed circuit board is formed to include a plurality of the wiring layers stacked on the substrate with the organic insulating layer in between, and
one or more of the wiring layers are formed through the wiring layer formation step, the organic insulating layer formation step, and the irradiation step.

10. The method of manufacturing an electronic element according to claim 1, wherein an organic thin-film solar cell is formed to include a transparent conductive layer as the wiring layer, a p-type organic semiconductor layer, an n-type organic semiconductor layer, a metal electrode layer as the wiring layer, and an organic insulating substrate as the organic insulating layer stacked in this order on the substrate, and
one or both of the transparent conductive layer and the metal electrode layer are formed through the wiring layer formation step, the organic insulating layer formation step, and the irradiation step.

11. The method of manufacturing an electronic element according to claim 1, wherein a touch panel is formed to include a first insulating layer as the organic insulating layer, a first transparent electrode as the wiring layer, a dielectric sheet as the organic insulating layer, a second transparent electrode as the wiring layer, and a second insulating layer as the organic insulating layer stacked in this order on the substrate, and
one or both of the first and second transparent electrodes are formed through the wiring layer formation step, the organic insulating layer formation step, and the irradiation step.

12. A method of manufacturing an electronic element for forming the electronic element including one or more wiring layer and an organic insulating layer stacked on a substrate, the method comprising:
a wiring layer formation step of forming the wiring layer on the substrate;
an organic insulating layer formation step of forming an organic insulating layer on the wiring layer; and
an irradiation step of irradiating a short-circuit portion of the wiring layer through the substrate with a laser beam having a wavelength transmissive through the substrate.

13. An electronic element comprising:
one or more wiring layers and an organic insulating layer stacked together on a substrate; and
a cavity enclosed by the wiring layer and the organic insulating layer or the substrate in contact with a top or bottom of the wiring layer, the cavity being provided in the same layer as the wiring layer.

14. The electronic element according to claim 13, wherein the electronic element is configured of an organic thin film transistor, including a lower metal layer as the wiring layer, a gate insulating film as the organic insulating layer, an organic semiconductor layer, an upper metal layer as the wiring layer, an interlayer insulating layer as the organic insulating layer, and a top metal layer as the wiring layer stacked in this order on the substrate, and
the electronic element has the cavity in the same layer as one or more of the lower metal layer, the upper metal layer, and the top metal layer.

15. The electronic element according to claim 13, wherein the electronic element is configured of a flexible printed circuit board, including a plurality of the wiring layers stacked on the substrate with the organic insulating layer in between, and
the electronic element has the cavity in the same layer as one or more of the wiring layers.

16. The electronic element according to claim 13, wherein the electronic element is configured of an organic thin-film solar cell, including a transparent conductive layer as the wiring layer, a p-type organic semiconductor layer, an n-type organic semiconductor layer, a metal electrode layer as the wiring layer, and an organic insulating substrate as the organic insulating layer stacked in this order on the substrate, and
the electronic element has the cavity in the same layer as one or both of the transparent conductive layer and the metal electrode layer.

17. The electronic element according to claim 13, wherein the electronic element is configured of a touch panel, including a first insulating layer as the organic insulating layer, a first transparent electrode as the wiring layer, a dielectric sheet as the organic insulating layer, a second transparent electrode as the wiring layer, and a second insulating layer as the organic insulating layer stacked in this order on the substrate, and
the electronic element has the cavity in the same layer as one or both of the first and second transparent electrodes.
